(19) United States
(12) Patent Application Publication
(10) Pub. No.: US 2024/0079415 A1
(43) Pub. Date: Mar. 7, 2024

(54) DISPLAY DEVICE AND DISPLAY SYSTEM

(71) Applicant: Japan Display Inc., Tokyo (JP)

(72) Inventors: Junko NAGASAWA, Tokyo (JP); Yuji MAEDE, Tokyo (JP)

(73) Assignee: Japan Display Inc., Tokyo (JP)

(21) Appl. No.: 18/461,546

(22) Filed: Sep. 6, 2023

(30) Foreign Application Priority Data
Sep. 7, 2022 (JP) 2022-142581

(51) Int. Cl. H01L 27/12; G02F 1/1362

(52) U.S. Cl. CPC H01L 27/124; G02F 1/136222; G02F 1/136286

(57) ABSTRACT

A display device includes an array substrate, and a counter substrate. The array substrate includes a plurality of signal lines arranged at an interval in a first direction, a plurality of scanning lines arranged at an interval in a second direction, a color filter, a plurality of pixel electrodes disposed for respective pixels, a common electrode superimposed on the plurality of pixel electrodes with an insulating film interposed between the common electrode and the plurality of pixel electrodes, and an insulating film covering the color filters. A contact hole is a recessed part opened through the insulating film and electrically couples the pixel electrode and the semiconductor, and a first flattening film is insulating and fills the recessed part of the contact hole.

### CROSS-REFERENCE TO RELATED APPLICATION

This application claims the benefit of priority from Japanese Patent Application No. 2022-142581 filed on Sep. 7, 2022, the entire contents of which are incorporated herein by reference.

### BACKGROUND

### 1. Technical Field

The present disclosure relates to a display device and a display system.

### 2. Description of the Related Art

Japanese Patent Application Laid-open Publication No. 2021-063897 (JP-A-2021-063897) discloses what is called a color-filter-on-array (COA) structure in which a color filter, a pixel electrode, and a common electrode are disposed on an array substrate side including a switching element.

In JP-A-2021-063897, no color filters are provided in a display region of a counter substrate to reduce influence of overlapping error between the array substrate and the counter substrate. In this configuration, color filters are provided on the array substrate and irregularity of the color filters is reduced by using a flattening film, and accordingly, the depth of a contact hole is relatively large. Furthermore, a spacer that maintains the inter-substrate distance between the array substrate and the counter substrate desirably has smaller overlapping error with the array substrate, and thus is directly formed on the array substrate by resin molding. However, in a case in which the spacer is adjacent to the contact hole, the solidification state of the spacer changes in accordance with the thickness of the flattening film in a recessed part of the contact hole, the flattening film filling the recessed part, and the shape of the spacer is potentially unstable.

The present disclosure is intended to provide a display device and a display system in which the shape of a spacer is stable.

### SUMMARY

A display device according to an embodiment includes an array substrate, and a counter substrate facing the array substrate. The array substrate includes a plurality of signal lines arranged at an interval in a first direction, a plurality of scanning lines arranged at an interval in a second direction, a color filter disposed at a position overlapping each opening surrounded by two adjacent signal lines and two adjacent scanning lines, a plurality of pixel electrodes disposed for respective pixels, a plurality of semiconductors disposed for respective pixels, a common electrode superimposed on the plurality of pixel electrodes with an insulating film interposed between the common electrode and the plurality of pixel electrodes, an insulating film covering the color filters, a contact hole that is a recessed part opened through the insulating film and electrically couples the pixel electrode and the semiconductor, a first flattening film that is insulating and fills the recessed part of the contact hole, a second flattening film overlapping at least the scanning lines and the first flattening film and directly covering the first flattening film from above, and a spacer that is made of resin, is disposed at each of parts where the signal lines intersect the scanning lines in a plan view, and regulates the distance between the array substrate and the counter substrate.

A display device according to an embodiment includes an array substrate, and a counter substrate facing the array substrate. The array substrate includes a plurality of signal lines arranged at an interval in a first direction, a plurality of scanning lines arranged at an interval in a second direction, a color filter disposed at a position overlapping each opening surrounded by two adjacent signal lines and two adjacent scanning lines, a plurality of pixel electrodes disposed for respective pixels, a plurality of semiconductors disposed for respective pixels, a common electrode superimposed on the plurality of pixel electrodes with an insulating film interposed between the common electrode and the plurality of pixel electrodes, an insulating film covering the color filters, a first contact hole that is a first recessed part opened through the insulating film and electrically couples a first pixel electrode among the plurality of pixel electrodes and the semiconductor, a flattening film that is insulating and fills the recessed part of the first contact hole, a second contact hole that is a second recessed part opened through the insulating film and electrically couples a second pixel electrode among the plurality of pixel electrodes and the semiconductor, a flattening film that is insulating and fills the recessed part of the second contact hole, and a first spacer that is made of resin, is disposed at each of parts where the signal lines intersect the scanning lines in a plan view, and regulates the distance between the array substrate and the counter substrate, and a second spacer that is made of resin, is disposed at each of other parts where the signal lines intersect the scanning lines, and regulates the distance between the array substrate and the counter substrate, the thickness of the flattening film that is insulating and fills the recessed part of the first contact hole is larger than the thickness of the flattening film that is insulating and fills the recessed part of the second contact hole, and the thickness of the first spacer is larger than the thickness of the second spacer.

A display device according to an embodiment includes an array substrate, and a counter substrate facing the array substrate. The array substrate includes a plurality of signal lines arranged at an interval in a first direction, a plurality of scanning lines arranged at an interval in a second direction, a color filter disposed at a position overlapping each opening surrounded by two adjacent signal lines and two adjacent scanning lines, a plurality of pixel electrodes disposed for respective pixels, a plurality of semiconductors disposed for respective pixels, a common electrode superimposed on the plurality of pixel electrodes with an insulating film interposed between the common electrode and the plurality of pixel electrodes, an insulating film covering the color filters, a contact hole that is a recessed part opened through the insulating film and electrically couples the pixel electrode and the semiconductor, a first flattening film that is insulating and fills the recessed part of the contact hole, a spacer that is made of resin, is disposed at each of parts where the signal lines intersect the scanning lines in a plan view, and regulates the distance between the array substrate and the counter substrate, and a conductive layer overlapping at least part of the scanning lines, and a region overlapping the spacer is a region in which the conductive layer is not formed.

A display system according to an embodiment includes a lens, the display device above, and a control device configured to output an image to the display device.

### BRIEF DESCRIPTION OF THE DRAWINGS

FIG. 1 is a configuration diagram illustrating an example of a display system according to a first embodiment;

FIG. 2 is a schematic diagram illustrating an example of the relative relation between a display device and an eye of a user;

FIG. 3 is a block diagram illustrating an example of the configuration of the display system according to the first embodiment;

FIG. 4 is a circuit diagram illustrating pixel arrangement of a display region according to the first embodiment;

FIG. 5 is a schematic diagram illustrating an example of a display panel according to the first embodiment;

FIG. 6 is a schematic diagram schematically illustrating part of the display region in the first embodiment in an enlarged manner;

FIG. 7 is a sectional view schematically illustrating a section along VII-VII′ in FIG. 6;

FIG. 8A is a sectional view schematically illustrating the boundary between the display region and a peripheral region according to the first embodiment;

FIG. 8B is a sectional view schematically illustrating the boundary between the display region and the peripheral region according to a modification of the first embodiment;

FIG. 9 is a sectional view schematically illustrating a section along IX-IX′ in FIG. 8A;

FIG. 10 is a sectional view schematically illustrating a section along X-X′ in FIG. 6;

FIG. 11A is a sectional view schematically illustrating the relation between the thickness of a first flat film and the thickness of a spacer;

FIG. 11B is a sectional view schematically illustrating the relation between the thickness of the first flat film and the thickness of the spacer;

FIG. 12A is a sectional view schematically illustrating the relation among the thickness of the first flat film, the thickness of a second flat film, and the thickness of the spacer;

FIG. 12B is a sectional view schematically illustrating the relation among the thickness of the first flat film, the thickness of the second flat film, and the thickness of the spacer;

FIG. 13 is a schematic diagram schematically illustrating part of the display region in a second embodiment in an enlarged manner;

FIG. 14 is a sectional view schematically illustrating an example of a section along XIV-XIV′ in FIG. 13 according to the second embodiment;

FIG. 15 is a sectional view schematically illustrating another example of the section along VII-VII′ in FIG. 6 according to a third embodiment;

FIG. 16 is a sectional view schematically illustrating another example of the section along VII-VII′ in FIG. 6 according to the third embodiment;

FIG. 17 is a schematic diagram schematically illustrating part of the display region in a fourth embodiment in an enlarged manner; and

FIG. 18 is a sectional view schematically illustrating an example of a section along XVIII-XVIII′ in FIG. 13 according to the fourth embodiment.

### DETAILED DESCRIPTION

Aspects (embodiments) of the present invention will be described below in detail with reference to the accompanying drawings. Contents described below in the embodiments do not limit the present disclosure. Constituent components described below include those that could be easily thought of by the skilled person in the art and those identical in effect. Constituent components described below may be combined as appropriate. What is disclosed herein is merely exemplary, and any modification that could be easily thought of by the skilled person in the art as appropriate without departing from the gist of the invention is contained in the scope of the present disclosure. For clearer description, the drawings are schematically illustrated for the width, thickness, shape, and the like of each component as compared to an actual aspect in some cases, but the drawings are merely exemplary and do not limit interpretation of the present disclosure. In the present specification and the drawings, any component same as that already described with reference to an already described drawing is denoted by the same reference sign, and detailed description thereof is omitted as appropriate in some cases.

### First Embodiment

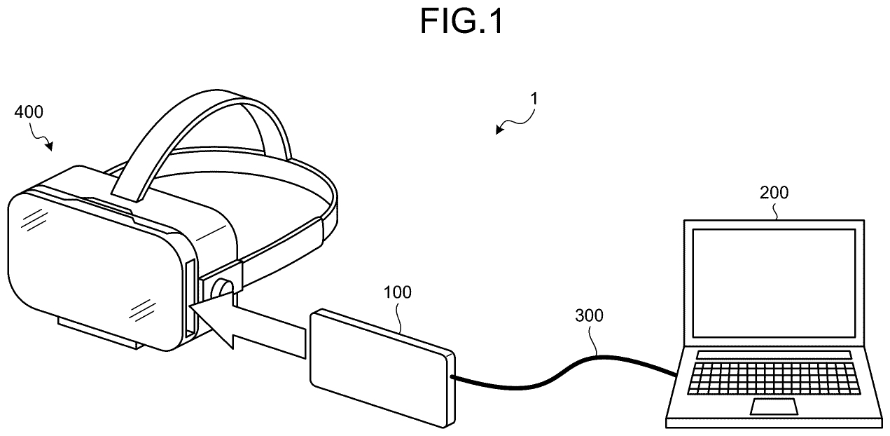

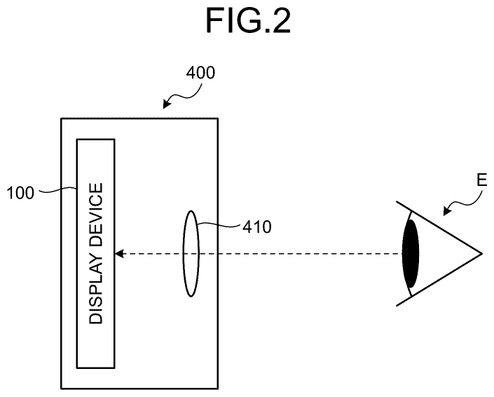

FIG. 1 is a configuration diagram illustrating an example of a display system according to a first embodiment. FIG. 2 is a schematic diagram illustrating an example of the relative relation between a display device and an eye of a user.

In the present embodiment, a display system 1 is a display system configured to change display along with motion of the user. For example, the display system 1 is a VR system configured to provide a virtual sense of reality to the user by stereoscopically displaying a virtual reality (VR) image illustrating a three-dimensional object or the like in a virtual space and changing the stereoscopic display along with the orientation (position) of the head of the user.

The display system 1 includes, for example, a display device 100 and a control device 200. Information (signal) can be input and output between the display device 100 and the control device 200 through a cable 300. The cable 300 includes, for example, a Universal Serial Bus (USB) or High-Definition Multimedia Interface (registered trademark) (HDMI) cable. Information may be input and output between the display device 100 and the control device 200 through wireless communication.

The display device 100 is supplied with electric force from the control device 200 through the cable 300. For example, the display device 100 may include a power receiver configured to be supplied with electric force from a power source of the control device 200 through the cable 300, and components of the display device 100 such as a display panel 110 and a sensor 120 may be driven by using the electric force supplied from the control device 200. With this configuration, a battery or the like can be omitted from the display device 100, and it is possible to provide the display device 100 that is more inexpensive and lightweight. A battery may be included in a mounting member 400 or the display device 100 so that electric power is supplied from the battery to the display device.

The display device 100 includes a display panel. The display panel is, for example, a liquid crystal display.

The display device 100 is fixed to the mounting member 400. The mounting member 400 includes, for example, a head set, goggles, and a helmet and a mask that cover the eyes of the user. The mounting member 400 is mounted on the head of the user. The mounting member 400 is disposed in front of the user to cover the eyes of the user when mounted. The mounting member 400 functions as an immersive mounting member when the display device 100 fixed inside is positioned in front of the eyes of the user. The mounting member 400 may include an outputter configured to output a sound signal or the like output from the control device 200. The mounting member 400 may have a structure with built-in functions of the control device 200.

The display device 100 is slotted in the mounting member 400 in the example illustrated in FIG. 1 but may be fixed to the mounting member 400. In other words, the display system may be constituted by a mounting display device and the control device 200, the display device including the mounting member 400 and the display device 100.

As illustrated in FIG. 2, the mounting member 400 includes, for example, a lens 410 corresponding to each eye of the user. The lens 410 is a magnifying lens for forming an image on the eye of the user. When mounted on the head of the user, the mounting member 400 positions the lens 410 in front of an eye E of the user. The user visually recognizes a display region of the display device 100 magnified through the lens 410. Thus, the display device 100 needs to have a high resolution to clearly display an image (screen). The configuration in which one lens is provided is exemplarily described in the present disclosure, but for example, a plurality of lenses may be provided and the display device 100 may be disposed at a position not in front of the eyes.

For example, the control device 200 displays an image on the display device 100. The control device 200 may be an electronic apparatus such as a personal computer or a game apparatus. Virtual images include images such as computer graphic videos and 360° live-action videos. The control device 200 outputs a three-dimensional image using the parallax of the eyes of the user to the display device 100. The control device 200 outputs right-eye and left-eye images that follow the orientation of the head of the user to the display device 100.

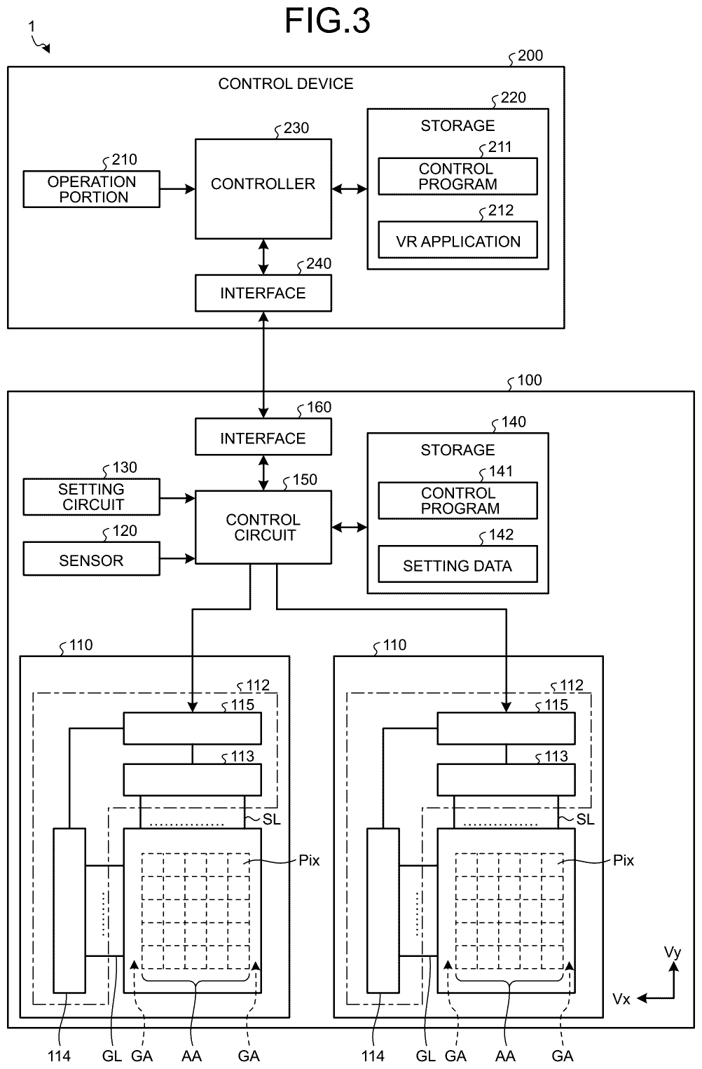

FIG. 3 is a block diagram illustrating an example of the configuration of the display system according to the first embodiment. As illustrated in FIG. 3, the display device 100 includes two display panels 110, the sensor 120, an image separation circuit 150, and an interface 160.

The display device 100 is constituted by the two display panels 110, one of which is used as a left-eye display panel 110 and the other of which is used as a right-eye display panel 110.

Each of the two display panels 110 includes a display region AA and a display control circuit 112. Each display panel 110 includes a non-illustrated light source device configured to irradiate the display region AA from behind.

The display region AA includes a two-dimensional matrix of rows and columns of P₀×Q₀ arranged pixels Pix (P₀ pixels in the row direction and Q₀ pixels in the column direction). In the present embodiment, P₀ is 2880 and Q₀ is 1700. FIG. 3 schematically illustrates arrangement of a plurality of pixels Pix, and detailed arrangement of pixels Pix will be described later. Since the pixels of the display device are visually recognized through the lens, the pixel pitch is, for example, 3 μm to 10 μm and the display region AA has high-definition arrangement of pixels Pix. The display region AA is surrounded by a peripheral region GA.

Each display panel 110 includes scanning lines extending in an X direction and signal lines extending in a Y direction intersecting the X direction. For example, the display panel 110 includes 2880 signal lines SL and 1700 scanning lines GL. In the display panel 110, each pixel Pix is disposed in a region surrounded by signal lines SL and scanning lines GL. Each pixel Pix includes a switching element SW (thin film transistor (TFT)) coupled to the signal line SL and the scanning line GL, and a pixel electrode coupled to the switching element SW. Each scanning line GL is coupled to a plurality of pixels Pix disposed in the direction in which the scanning line GL extends. Each signal line SL is coupled to a plurality of pixels Pix disposed in the direction in which the signal line SL extends.

The display region AA of one of the two display panels 110 is for the right eye, and the display region AA of the other display panel 110 is for the left eye. The first embodiment will be described for a case in which the display panels 110 include the two display panels 110 for the left and right eyes. However, the display device 100 is not limited to a structure including the two display panels 110 as described above. For example, one display panel 110 may be provided, and the display region of the one display panel 110 may divided into two to display a right-eye image in the right-half region and display a left-eye image in the left-half region.

The display control circuit 112 includes a driver integrated circuit (IC) 115, a signal line coupling circuit 113, and a scanning line drive circuit 114. The signal line coupling circuit 113 is electrically coupled to the signal lines SL. The driver IC 115 controls the scanning line drive circuit 114 to turn on and off each switching element (for example, TFT) for controlling operation (light transmittance) of the corresponding pixel Pix. The scanning line drive circuit 114 is electrically coupled to the scanning lines GL.

The sensor 120 detects information based on which the orientation of the head of the user can be estimated. For example, the sensor 120 detects information indicating motion of the display device 100 and the mounting member 400, and the display system 1 estimates the orientation of the head of the user on which the display device 100 is mounted based on the information indicating motion of the display device 100 and the mounting member 400.

The sensor 120 detects information based on which the orientation of the line of sight can be estimated by using, for example, at least one of the angles, accelerations, angular velocities, orientations, and distances of the display device 100 and the mounting member 400. The sensor 120 may be, for example, a gyro sensor, an acceleration sensor, or an orientation sensor. For example, the sensor 120 may detect the angles and angular velocities of the display device 100 and the mounting member 400 by using the gyro sensor. For example, the sensor 120 may detect the direction and magnitude of acceleration applied to the display device 100 and the mounting member 400 by using the acceleration sensor. For example, the sensor 120 may detect the orientation of the display device 100 by using the orientation sensor. For example, the sensor 120 may detect movement of the display device 100 and the mounting member 400 by using a distance sensor, a global positioning system (GPS) receiver, or the like. The sensor 120 may be any other sensor, such as a light sensor, for detecting the orientation of the head of the user, change of the line of sight, movement, or the like, or may be a combination of a plurality of sensors. The sensor 120 is electrically coupled to the image separation circuit 150 through the interface 160 to be described later.

The image separation circuit 150 receives left-eye image data and right-eye image data fed from the control device 200 through the cable 300, feeds the left-eye image data to the display panel 110 configured to display a left-eye image, and feeds the right-eye image data to the display panel 110 configured to display a right-eye image.

The interface 160 includes a connector to which the cable 300 (FIG. 1) is coupled. A signal from the control device 200 is input to the interface 160 through the coupled cable 300. The image separation circuit 150 outputs a signal input from the sensor 120 to the control device 200 through the interface 160 and an interface 240. The signal input from the sensor 120 includes the above-described information based on which the orientation of the line of sight can be estimated. Alternatively, the signal input from the sensor 120 may be directly output to a controller 230 of the control device 200 through the interface 160. The interface 160 may be, for example, a wireless communication device and may transmit and receive information to and from the control device 200 through wireless communication.

The control device 200 includes an operation portion 210, a storage 220, the controller 230, and the interface 240.

The operation portion 210 receives an operation from the user. The operation portion 210 may be an input device such as a keyboard, a button, or a touch screen. The operation portion 210 is electrically coupled to the controller 230. The operation portion 210 outputs information in accordance with the operation to the controller 230.

The storage 220 stores computer programs and data. The storage 220 temporarily stores results of processing by the controller 230. The storage 220 includes a storage medium. Examples of the storage medium include a ROM, a RAM, a memory card, an optical disk, and a magneto optical disc. The storage 220 may store data of images to be displayed on the display device 100.

The storage 220 stores, for example, a control program 211 and a VR application 212. The control program 211 can provide, for example, functions related to various kinds of control for operating the control device 200. The VR application 212 can provide a function to display a virtual reality image on the display device 100. The storage 220 can store various kinds of information input from the display device 100, such as data indicating results of detection by the sensor 120.

The controller 230 includes, for example, a micro control unit (MCU) or a central processing unit (CPU). The controller 230 can collectively control operation of the control device 200. Various kinds of functions of the controller 230 are implemented based on control by the controller 230.

The controller 230 includes, for example, a graphics processing unit (GPU) configured to generate an image to be displayed. The GPU generates an image to be displayed on the display device 100. The controller 230 outputs the image generated by the GPU to the display device 100 through the interface 240. The controller 230 of the control device 200 includes the GPU in description of the present embodiment but is not limited thereto. For example, the GPU may be provided in the display device 100 or the image separation circuit 150 of the display device 100. In this case, the display device 100 may acquire data from the control device 200, an external electronic apparatus, or the like, and the GPU may generate an image based on the data.

The interface 240 includes a connector to which the cable 300 (refer to FIG. 1) is coupled. A signal from the display device 100 is input to the interface 240 through the cable 300. The interface 240 outputs a signal input from the controller 230 to the display device 100 through the cable 300. The interface 240 may be, for example, a wireless communication device and may transmit and receive information to and from the display device 100 through wireless communication.

When the VR application 212 is executed, the controller 230 displays an image on the display device 100 in accordance with motion of the user (display device 100). When having detected change of the user (display device 100) while displaying the image on the display device 100, the controller 230 changes the image displayed on the display device 100 to an image in the direction of the change. At start of image production, the controller 230 produces an image based on a reference viewpoint and a reference line of sight in a virtual space, and when having detected change of the user (display device 100), changes a viewpoint or the line of sight for producing a displayed image from the direction of the reference viewpoint or the reference line of sight in accordance with motion of the user (display device 100), and displays an image based on the changed viewpoint or line of sight on the display device 100.

For example, the controller 230 detects rightward movement of the head of the user based on a result of detection by the sensor 120. In this case, the controller 230 changes a currently displayed image to an image when the line of sight is changed in the right direction. The user can visually recognize an image to the right of the image displayed on the display device 100.

For example, when having detected movement of the display device 100 based on a result of detection by the sensor 120, the controller 230 changes an image in accordance with the detected movement. When having detected frontward movement of the display device 100, the controller 230 changes the currently displayed image to an image in a case of movement to the front side of the currently displayed image. When having detected backward movement of the display device 100, the controller 230 changes the currently displayed image to an image in a case of movement to the back side of the currently displayed image. The user can visually recognize an image in the direction in which the user moves from an image displayed on the display device 100.

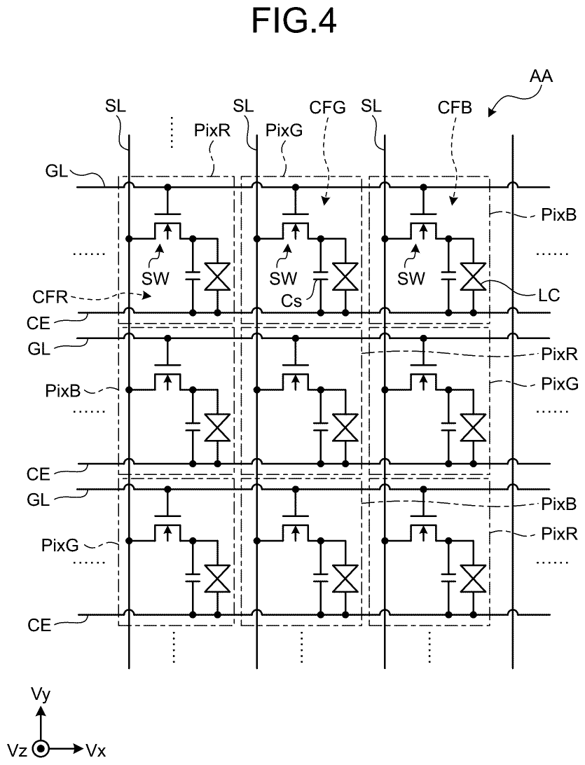

FIG. 4 is a circuit diagram illustrating pixel arrangement of the display region according to the first embodiment. In the present disclosure, the scanning lines GL do not necessarily need to intersect the signal lines SL at right angle, but in FIG. 3, the scanning lines GL intersect the signal lines SL at right angle for the purpose of illustration.

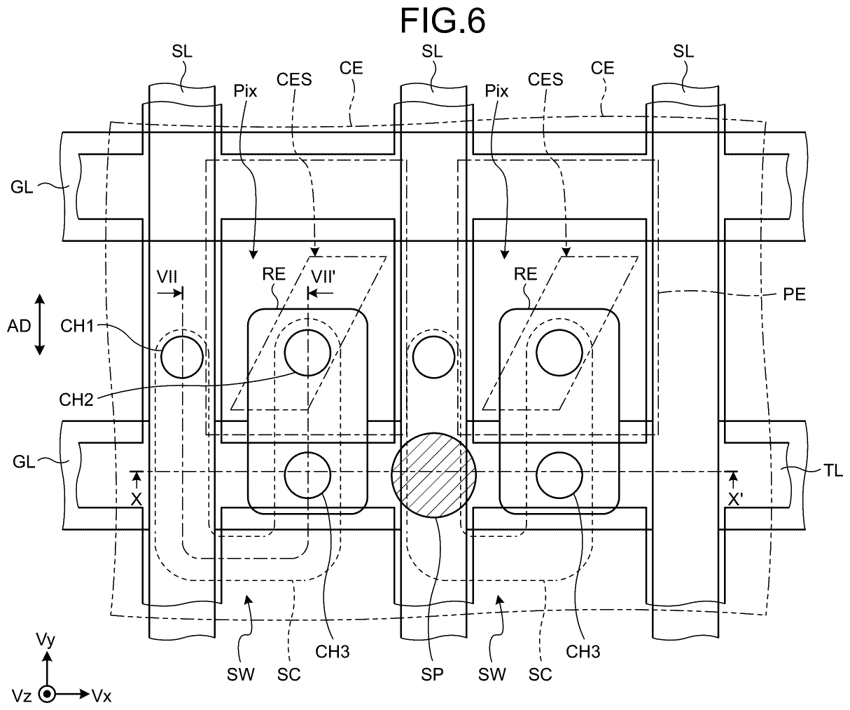

The switching elements SW of pixels PixR, PixG, and PixB, the signal lines SL, the scanning lines GL illustrated in FIG. 4 are formed in each display region AA. The signal lines SL are wires for supplying pixel signals to pixel electrodes PE (refer to FIG. 6). The scanning lines GL are wires for supplying gate signals that drive the switching elements SW.

As illustrated in FIG. 4, the pixels PixR, PixG, and PixB include the respective switching elements SW and capacitors of a liquid crystal layer LC. The switching element SW is constituted by a thin film transistor, and in this example, constituted by an n-channel metal oxide semiconductor (MOS) TFT. An insulating film is provided between the pixel electrodes PE and a common electrode CE to be described later, and holding capacitors Cs illustrated in FIG. 4 are formed between the pixel electrodes PE and the common electrode CE.

Color filters CFR1, CFG1, and CFB1 illustrated in FIG. are periodically arranged color regions colored in, for example, three colors of red (first color: R), green (second color: G), and blue (third color: B). The above-described pixels PixR, PixG, and PixB illustrated in FIG. 4 are associated with the color regions in the three colors of R, G, and B. The pixels PixR, PixG, and PixB corresponding to the color regions in the three colors are grouped as a set of pixels. The color filters may include color regions in four or more colors. The pixels PixR, PixG, and PixB are also called sub pixels.

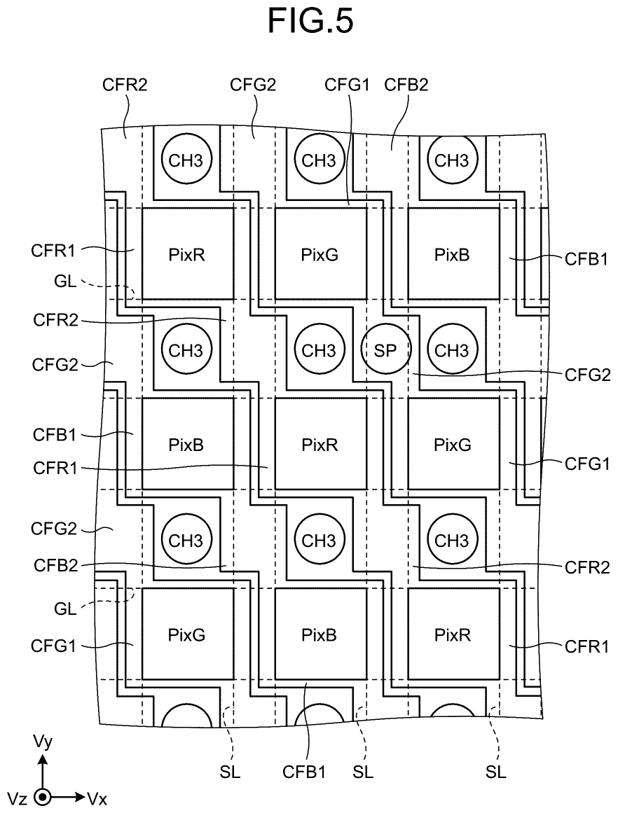

The color filters CFR1, CFG1, and CFB1 illustrated in FIG. 5 are each disposed at an opening part surrounded by two signal lines SL and two scanning lines GL.

As illustrated in FIGS. 4 and 5, the pixel PixR is sandwiched between the pixel PixB and the pixel PixG in a direction Vx (first direction), and the pixel PixR is sandwiched between the pixel PixB and the pixel PixG in a direction Vy (second direction).

The pixel PixG is sandwiched between the pixel PixR and the pixel PixB in the direction Vx, and the pixel PixG is sandwiched between the pixel PixR and the pixel PixB in the direction Vy.

The pixel PixB is sandwiched between the pixel PixG and the pixel PixR in the direction Vx, and the pixel PixB is sandwiched between the pixel PixG and the pixel PixR in the direction Vy.

The pixels PixR, PixG, and PixB are repeatedly arranged in this order in the direction Vx. The pixels PixR, PixB, and PixG are repeatedly arranged in this order in the direction Vy. The arrangement in the direction Vy may be repeatedly arranged in the order of the pixels PixR, PixG, and PixB.

The color filters CFR1 are coupled to each other through a color filter CFR2 in the same color of red, and the color filters in the same color are disposed in an oblique direction intersecting each of the directions Vx and Vy when the color filters CFR1 are coupled to the color filter CFR2. Similarly, the color filters CFG1 are coupled to each other through a color filter CFG2 in the same color of green, and the color filters CFB1 are coupled to each other through a color filter CFB2 in the same color of blue.

The color filters CFR1 and CFR2 are integrally formed, and thus when not distinguished from each other, the color filters CFR1 and CFR2 are referred to as color filters CFR below for sake of simplicity of description. Similarly, when not distinguished from each other, the color filters CFG1 and CFG2 are referred to as color filters CFG below. When not distinguished from each other, the color filters CFB1 and CFB2 are referred to as color filters CFB below. When not distinguished from one another, the color filters CFR, CFG, and CFB are referred to as color filters CF.

A spacer SP illustrated in FIG. 5 is a member that regulates the distance between an array substrate SUB1 and a counter substrate SUB2. The material of the spacer SP is, for example, acrylic resin. The spacer SP is cylindrical and the maximum radius of the spacer SP is illustrated in FIG. 5. The shape of the spacer SP is not limited to a cylindrical shape and the spacer SP may be formed as, for example, a spacer in a rectangular column shape. Although FIG. 5 exemplarily illustrates one spacer, a plurality of spacers are disposed in reality.

A pixel Pix illustrated in FIG. 6 is any of the pixels PixR, PixG, and PixB. Hereinafter, when not distinguished from one another, the pixels PixR, PixG, and PixB are referred to as pixels Pix.

The signal lines SL are arranged at an interval in the direction Vx. The scanning lines GL are arranged at an interval in the direction Vy. A conductive layer TL has a lattice shape and is superimposed on the signal lines SL and the scanning lines GL in a plan view. The width of the conductive layer TL in the direction Vx is larger than the width of each signal line SL in the direction Vx. The width of each scanning line GL in the direction Vy is larger than the width of the conductive layer TL in the direction Vy.

The pixel electrodes PE and the switching elements SW are disposed in the pixels Pix at the respective opening parts surrounded by two signal lines SL and two scanning lines GL. The common electrode CE is common to the pixels Pix. The common electrode CE has a slit CES at each opening part surrounded by two signal lines SL and two scanning lines GL. The slit CES is a part at which a translucent conductive material of the common electrode CE is not provided. The slit CES overlaps the corresponding pixel electrode PE.

As illustrated in FIG. 6, a semiconductor SC is formed in a U shape. The semiconductor SC is electrically coupled to a signal line SL through a contact hole CH1. The semiconductor SC is electrically coupled to a relay electrode RE through a contact hole CH2. The relay electrode RE is electrically coupled to a pixel electrode PE through a contact hole CH3.

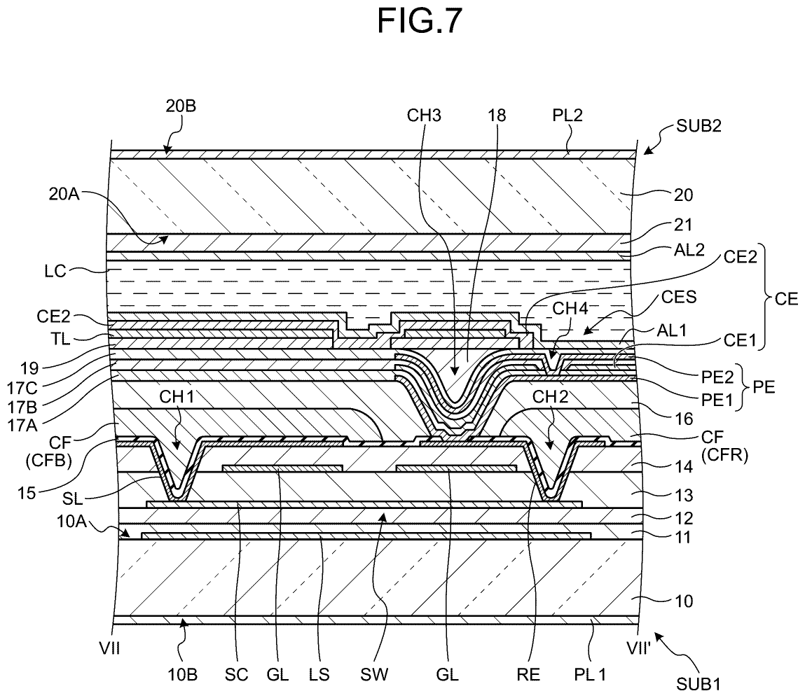

FIG. 7 is a sectional view schematically illustrating a section along VII-VII′ in FIG. 6. In the first embodiment, the color filter CF is provided on the array substrate SUB1 as illustrated in FIG. 5. The display device 100 has what is called a Color Filter on Array (COA) structure in which the color filters CF, the pixel electrodes PE, and the common electrode CE are disposed on the array substrate SUB1.

As illustrated in FIG. 7, the array substrate SUB1 is based on a translucent first insulation substrate 10 such as a glass substrate or a resin substrate. The array substrate SUB1 includes a light-shielding layer LS, a first insulating film 11, a second insulating film 12, a third insulating film 13, a fourth insulating film 14, the color filters CF, a fifth insulating film 15, a pixel electrode PE1, a sixth insulating film 16, a common electrode CE1, a seventh insulating film 17, a pixel electrode PE2, a first flattening film 18, a second flattening film 19, the conductive layer TL, a common electrode CE2, and a first alignment film AL1 on a side on which the first insulation substrate 10 faces the counter substrate SUB2. In the following description, the direction from the array substrate SUB1 toward the counter substrate SUB2 is referred to as upward or up.

The light-shielding layer LS is positioned on the first insulation substrate 10. The first insulating film 11 is positioned on the light-shielding layer LS and an inner side surface 10A of the first insulation substrate 10. The second insulating film 12 is positioned on the first insulating film 11. The semiconductor SC is positioned on the second insulating film 12. The third insulating film 13 is positioned on the semiconductor SC and the second insulating film 12. Gate electrodes of the scanning lines GL are positioned on the third insulating film 13.

The fourth insulating film 14 is positioned on the gate electrodes of the scanning lines GL and the third insulating film 13. The contact hole CH1 is formed through the third insulating film 13 and the fourth insulating film 14 at a position overlapping the semiconductor SC, and a signal line SL formed on the fourth insulating film 14 is electrically coupled to the semiconductor SC through the contact hole CH1.

The contact hole CH2 is formed through the third insulating film 13 and the fourth insulating film 14 at a position overlapping the semiconductor SC, and the relay electrode RE formed on the fourth insulating film 14 is electrically coupled to the semiconductor SC through the contact hole CH2.

The fifth insulating film 15 is positioned on the signal lines SL, the relay electrode RE, and the fourth insulating film 14. The color filters CF are positioned on the fifth insulating film 15. The sixth insulating film 16 is positioned on the color filters CF and the fifth insulating film 15.

The contact hole CH3 is formed through the fifth insulating film 15 and the sixth insulating film 16 at a position overlapping the relay electrode RE, and the pixel electrode PE1 is electrically coupled to the relay electrode RE through the contact hole CH3. A first middle insulating film 17A is positioned on the sixth insulating film 16 and the pixel electrode PE1. The pixel electrode PE1 is formed of a translucent conductive material such as indium tin oxide (ITO), indium zinc oxide (IZO), or indium gallium oxide (IGO).

The common electrode CE1 is positioned on the first middle insulating film 17A. The common electrode CE1 is formed of a translucent conductive material such as ITO, IZO, or IGO. A second middle insulating film 17B is positioned on the common electrode CE1 and the first middle insulating film 17A. The pixel electrode PE2 is positioned on the second middle insulating film 17B. The pixel electrode PE2 is formed of a translucent conductive material such as ITO, IZO, or IGO. A contact hole CH4 is formed through the second middle insulating film 17B. The pixel electrode PE2 and the common electrode CE1 are electrically insulated from each other through the second middle insulating film 17B, through the contact hole CH4, and the pixel electrode PE2 is electrically connected to the pixel electrode PE1.

A third middle insulating film 17C is positioned on the pixel electrode PE2 and the second middle insulating film 17B. The first middle insulating film 17A, the second middle insulating film 17B, and the third middle insulating film 17C are a seventh insulating film.

A recessed part of the front surface of the third middle insulating film 17C is formed in the contact hole CH3 and thus flattened by the first flattening film 18. The second flattening film 19 is positioned on the third middle insulating film 17C and the first flattening film 18.

The material of the first flattening film 18 is novolak resin or acrylic resin. The material of the second flattening film 19 may be the same as or different from that of the first flattening film 18. The second flattening film 19 is an inorganic insulating film made of silicon nitride or the like or is an organic insulating film made of novolak resin, acrylic resin, or the like.

The conductive layer TL is positioned on the second flattening film 19. Since the conductive layer TL is a conductor and electrically coupled to the common electrode CE, the resistance values of the common electrode CE and the conductive layer TL per unit area are small. The conductive layer TL may be a single layer of a metal such as aluminum (Al) but may be formed of a plurality of metal layers such as titanium/aluminum/titanium or molybdenum/aluminum/molybdenum with titanium (Ti) or molybdenum (Mo) disposed above and below aluminum.

The common electrode CE2 is positioned on the conductive layer TL and the second flattening film 19. The common electrode CE2 and the slit CES are covered by the first alignment film AL1.

The counter substrate SUB2 is based on a translucent second insulation substrate 20 such as a glass substrate or a resin substrate. The counter substrate SUB2 is provided with an overcoat layer 21 and a second alignment film AL2 on a side on which the second insulation substrate 20 faces the array substrate SUB1.

The array substrate SUB1 and the counter substrate SUB2 described above are disposed such that the first alignment film AL1 and the second alignment film AL2 face each other. The liquid crystal layer LC is encapsulated between the first alignment film AL1 and the second alignment film AL2. The first alignment film AL1 and the second alignment film AL2 orient the long axis of each liquid crystal molecule in parallel to an initial orientation direction AD illustrated in FIG. 6. The liquid crystal layer LC is made of a negative liquid crystal material having negative dielectric constant anisotropy or a positive liquid crystal material having positive dielectric constant anisotropy.

The array substrate SUB1 faces a backlight unit, and the counter substrate SUB2 is positioned on a display surface side. The backlight unit is applicable in various kinds of forms, but description of a detailed structure thereof is omitted.

A first optical element OD1 including a first polarization plate PL1 is disposed on an outside surface 10B of the first insulation substrate 10 or its surface facing the backlight unit. A second optical element OD2 including a second polarization plate PL2 is disposed on an outside surface 20B of the second insulation substrate 20 or its surface on an observation position side. A first polarization axis of the first polarization plate PL1 and a second polarization axis of the second polarization plate PL2 are in, for example, a cross Nicol positional relation on a Vx-Vy plane. The first optical element OD1 and the second optical element OD2 may each include another optical function element such as a wave plate.

For example, in a state in which no voltage is applied to the liquid crystal layer LC when the liquid crystal layer LC is a negative liquid crystal material, the long axis of each liquid crystal molecule LM is initially oriented in a predetermined direction on a Vx-Vy plane. In a state in which voltage is applied to the liquid crystal layer LC, in other words, in an “on” state in which an electric field is formed between the pixel electrodes PE and the common electrode CE, the orientation state of the liquid crystal molecule LM changes due to influence of the electric field. In the “on” state, the polarization state of incident linearly polarized light changes in accordance with the orientation state of the liquid crystal molecule LM as the light passes through the liquid crystal layer LC.

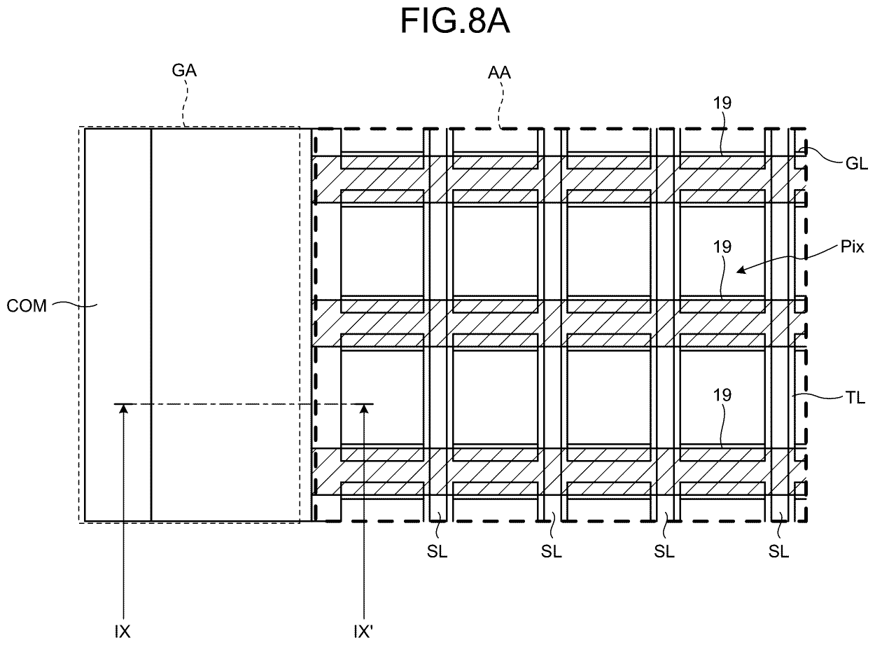

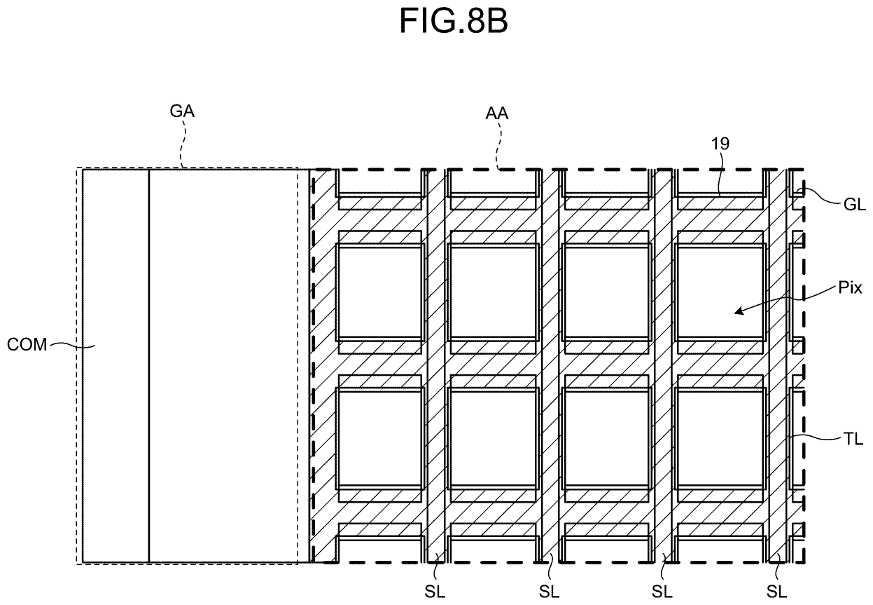

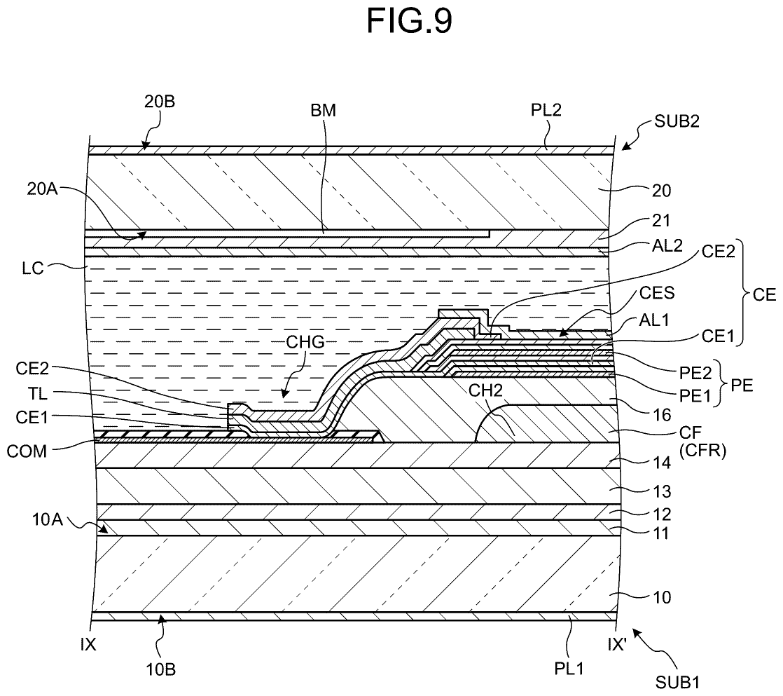

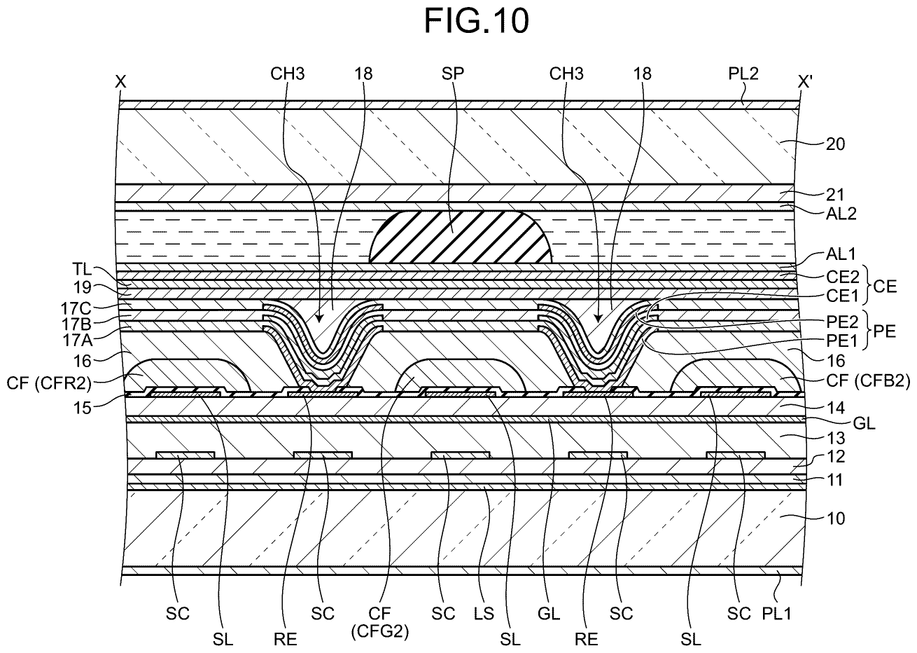

FIG. 8A is a sectional view schematically illustrating the boundary between the display region and the peripheral region according to the first embodiment. FIG. 8B is a sectional view schematically illustrating the boundary between the display region and the peripheral region according to a modification of the first embodiment. FIG. 9 is a sectional view schematically illustrating a section along IX-IX′ in FIG. 8A. FIG. 10 is a sectional view schematically illustrating the section along X-X′ in FIG. 6.

As illustrated in FIGS. 8A, 8B, and 9, a wire COM for supplying common potential is disposed on the fourth insulating film 14 in the peripheral region GA. The fifth insulating film 15 covers and protects the wire COM. A contact hole CHG is provided at part of the fifth insulating film 15, and the wire COM is electrically coupled through the contact hole CHG to the common electrode CE1, the conductive layer TL, and the common electrode CE2 extending from the display region AA.

As illustrated in FIG. 8A, the second flattening film 19 is formed along the scanning lines GL and shaped in strips. The area of each strip of the second flattening film 19 is equal to or smaller than the area of the corresponding scanning line GL. More preferably, the area of each strip of the second flattening film 19 is smaller than the area of the corresponding scanning line GL with positional shift taken into account. Accordingly, each strip of the second flattening film 19 is formed inside the corresponding scanning line GL. No second flattening film 19 is provided inside each opening surrounded by two adjacent lines of the conductive layer TL formed along signal lines SL and two adjacent scanning lines GL. As a result, the second flattening film 19 does not cover the slit CES in each opening and does not suppress electric field from the pixel electrodes PE.

As illustrated in FIGS. 8A and 9, in the peripheral region GA, a light-shielding layer BM is provided on the counter substrate SUB2 and hides the peripheral region GA of the array substrate SUB1. As illustrated in FIGS. 7 and 9, no light-shielding layer BM is provided on the counter substrate SUB2 in the display region AA. The light-shielding layer BM is formed of a black resin material.

As illustrated in FIG. 8B, the second flattening film 19 may be formed along the conductive layer TL and have a lattice shape. The area of each line of the second flattening film 19 is equal to or smaller than the area of the corresponding line of the conductive layer TL. More preferably, the area of each line of the second flattening film 19 is smaller than the area of the corresponding line of the conductive layer TL with positional shift taken into account. Accordingly, each line of the second flattening film 19 is formed inside the corresponding scanning line GL. No second flattening film 19 is provided inside each opening surrounded by two adjacent lines of the conductive layer TL formed along signal lines SL and two adjacent scanning lines GL. As a result, the second flattening film 19 does not cover the slit CES in each opening and does not suppress electric field from the pixel electrodes PE.

In a structure of a comparative example in which color filters and light-shielding layers at the boundaries between the colors of the color filters are provided on the counter substrate SUB2 unlike the first embodiment, the positions of the light-shielding layers in the display region AA on the counter substrate SUB2 are more likely to overlap openings for pixels Pix trough the array substrate as the pixels Pix are smaller. However, in the COA structure of the first embodiment illustrated in FIGS. 8A and 9, no color filters CF nor light-shielding layers at the boundaries between the colors of the color filters CF are provided in the display region AA on the counter substrate SUB2, and thus no light-shielding is provided at openings for pixels Pix even when the pixels Pix are small.

However, since the color filters CF have thickness, irregularity of the color filters CF is reduced by the sixth insulating film 16. Accordingly, the contact hole CH3 opened through the sixth insulating film 16 has a large depth. The first flattening film 18 fills a recessed part of the contact hole CH3 to reduce influence of the recessed part of the contact hole CH3.

However, since the contact hole CH3 is deep, variance potentially occurs to the thickness of the first flattening film 18. As illustrated in FIGS. 5 and 10, the spacer SP is disposed at each of parts where the signal lines SL intersect the scanning lines GL.

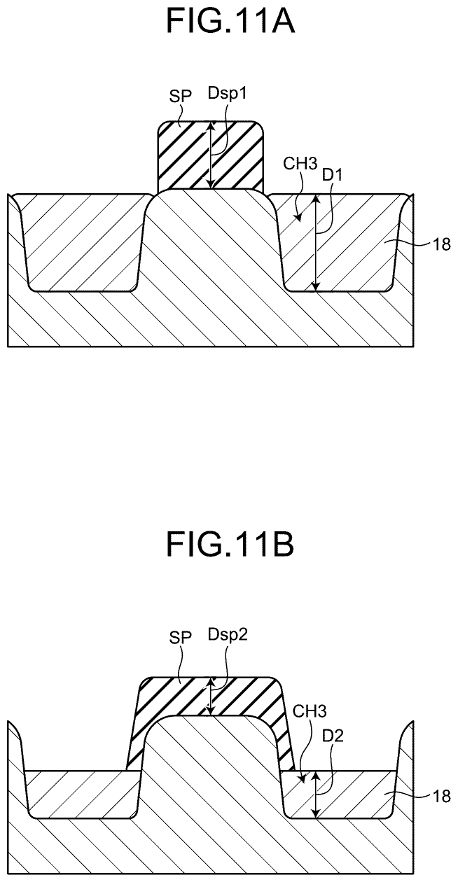

FIGS. 11A and 11B are sectional views schematically illustrating the relation between the thickness of a first flat film and the thickness of the spacer. In a case in which no second flattening film 19 is provided, the spacer SP has a thickness Dsp1 in accordance with a thickness D1 of the first flattening film 18 illustrated in FIG. 11A and has a thickness Dsp2 in accordance with a thickness D2 of the first flattening film 18 illustrated in FIG. 11B. The first flattening film 18 is further recessed as the thickness D1 of the first flattening film 18 decreases to the thickness D2. As a result, part of the material of the spacer SP during deposition flows into the recess of the first flattening film 18, and the thickness Dsp1 of the spacer SP decreases to the thickness Dsp2.

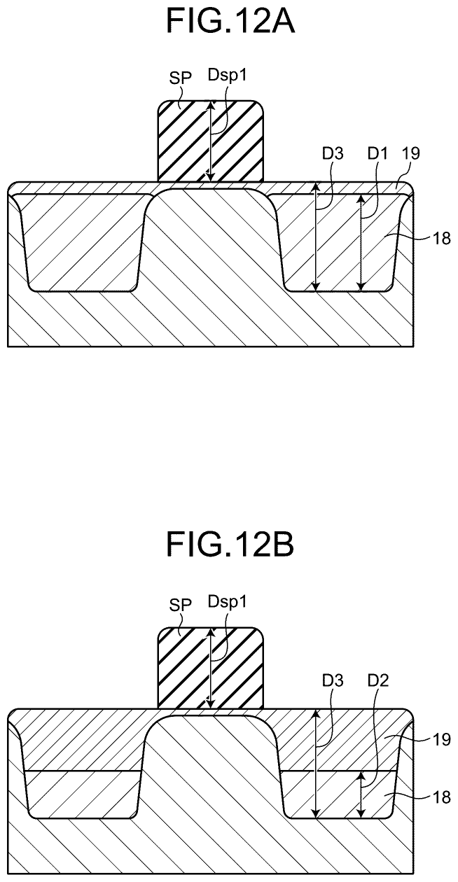

FIGS. 12A and 12B are sectional views schematically illustrating the relation among the thickness of the first flat film, the thickness of a second flat film, and the thickness of the spacer. In a case in which the second flattening film 19 is provided, the difference between the thickness D1 of the first flattening film 18 illustrated in FIG. 12A and the thickness D2 of the first flattening film 18 illustrated in FIG. 12B is compensated by the second flattening film 19. At the contact hole CH3, the total thickness of the first flattening film 18 and the second flattening film 19 is substantially equal to a thickness D3, and variance of the recess of the contact hole CH3 decreases. As a result, the thickness Dsp1 of the spacer has a stable value.

As described above, the display device 100 includes the array substrate SUB1, and the counter substrate SUB2 facing the array substrate SUB1. No light-shielding layer is provided in the display region AA of the counter substrate SUB2. Accordingly, influence of overlap misalignment between the array substrate SUB1 and the counter substrate SUB2 is reduced.

The array substrate SUB1 includes the signal lines SL arranged at an interval in the direction Vx and the scanning lines GL arranged at an interval in the direction Vy. Each color filter CF of the array substrate SUB1 is disposed at a position overlapping an opening surrounded by two of the signal lines SL adjacent to each other and two of the scanning lines GL adjacent to each other. The array substrate SUB1 includes the pixel electrodes PE disposed for the respective pixels Pix, and the common electrode CE superimposed on the pixel electrodes PE through an insulating film.

The sixth insulating film 16 covers the color filters CF. The contact hole CH3 is a recessed part opened through the sixth insulating film 16 and electrically couples each pixel electrode PE and the corresponding semiconductor SC through the relay electrode RE. The first flattening film 18 is an insulating film that fills the recessed part of the contact hole CH3.

The second flattening film 19 overlaps the scanning lines GL in a plan view. The second flattening film 19 directly covers the first flattening film 18 from above. The spacer SP is made of resin and disposed at each of parts where the signal lines SL intersect the scanning lines GL in a plan view. The spacer SP is sandwiched in a plan view between the contact holes CH3 adjacent to each other in the direction (direction Vx) in which the scanning lines GL extend.

In the first embodiment, irregularity due to the contact hole CH3 is reduced, the accuracy of the shape of the spacer SP is stabilized, and the accuracy of regulation of the distance between the array substrate SUB1 and the counter substrate SUB2 by the spacer SP is increased.

### Second Embodiment

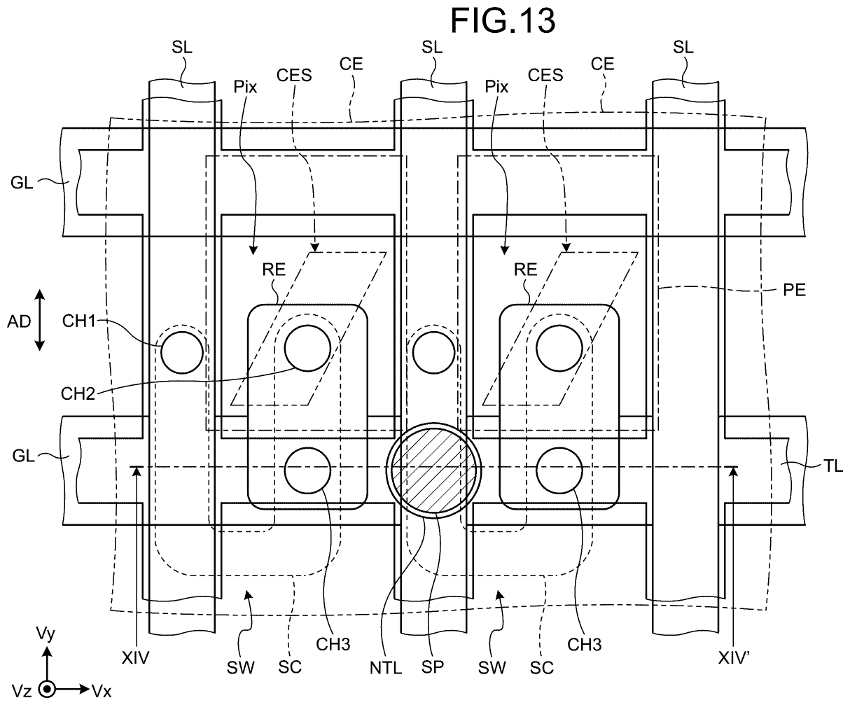

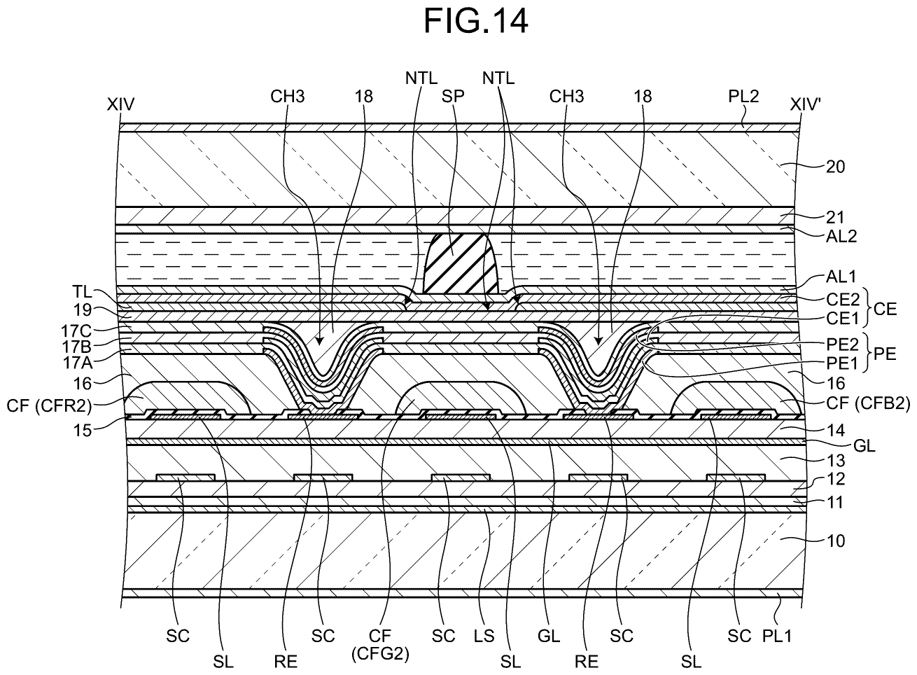

FIG. 13 is a schematic diagram schematically illustrating part of the display region in a second embodiment in an enlarged manner. FIG. 14 is a sectional view schematically illustrating an example of a section along XIV-XIV′ in FIG. 13 according to the second embodiment. In the following description, any same constituent component is denoted by the same reference sign in some cases. Any duplicate description is omitted. The shape accuracy of the spacer SP is potentially affected in a case in which the conductive layer TL has metal glazing.

As illustrated in FIGS. 13 and 14, a region overlapping the spacer SP in the second embodiment is a region NTL in which the conductive layer TL is not formed.

In the non-formation region NTL, the first alignment film AL1 covers the second flattening film 19. Reflected light due to metal glazing of the conductive layer TL reduces in the non-formation region NTL. Thus, the spacer SP is unlikely to be affected by exposure in a molding process, and accordingly, the accuracy of the shape of the spacer is stabilized.

### Third Embodiment

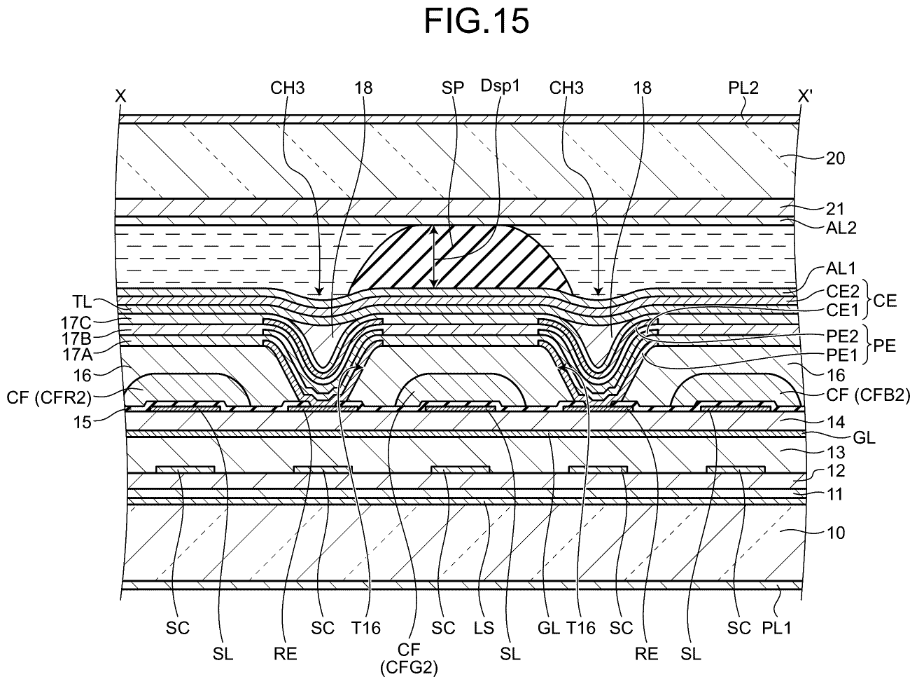

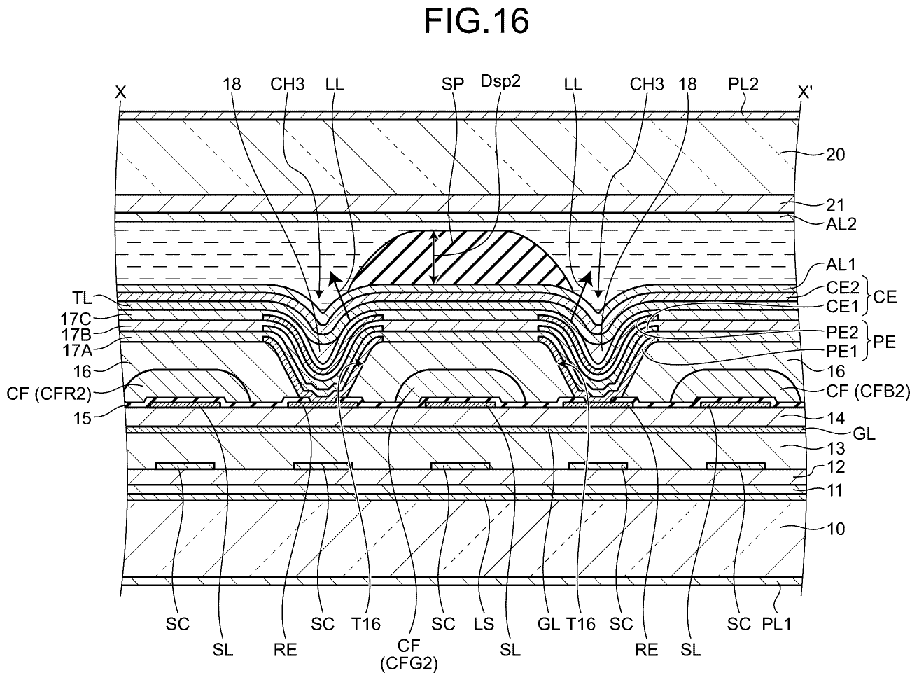

FIG. 15 is a sectional view schematically illustrating another example of the section along VII-VII′ in FIG. 6 according to a third embodiment. FIG. 16 is a sectional view schematically illustrating another example of the section along VII-VII′ in FIG. 6 according to the third embodiment. In the following description, any constituent component same as in the first and second embodiments is denoted by the same reference sign, and duplicate description thereof is omitted.

In the third embodiment, no second flattening film 19 is provided unlike the first embodiment. As illustrated in FIGS. 11A and 11B, the thickness of the spacer SP changes in accordance with the thickness of the first flattening film 18.

A plurality of spacers SP are formed in the display panel 110. A first spacer SP illustrated in FIG. 15 is disposed at a position different from the position of a second spacer SP illustrated in FIG. 16. The thickness of the first flattening film 18 that is insulating and fills a recessed part of a first contact hole CH3 illustrated in FIG. 15 is larger than the thickness of the first flattening film 18 that is insulating and fills a recessed part of a second contact hole CH3 illustrated in FIG. 16. The thickness Dsp1 of the first spacer SP illustrated in FIG. 15 is larger than the thickness Dsp2 of the second spacer SP illustrated in FIG. 16.

As described above, the display panel 110 includes the plurality of spacers SP having a plurality of thicknesses. As a result, the plurality of spacers SP regulate the distance between the array substrate SUB1 and the counter substrate SUB2 at a plurality of stages.

### Fourth Embodiment

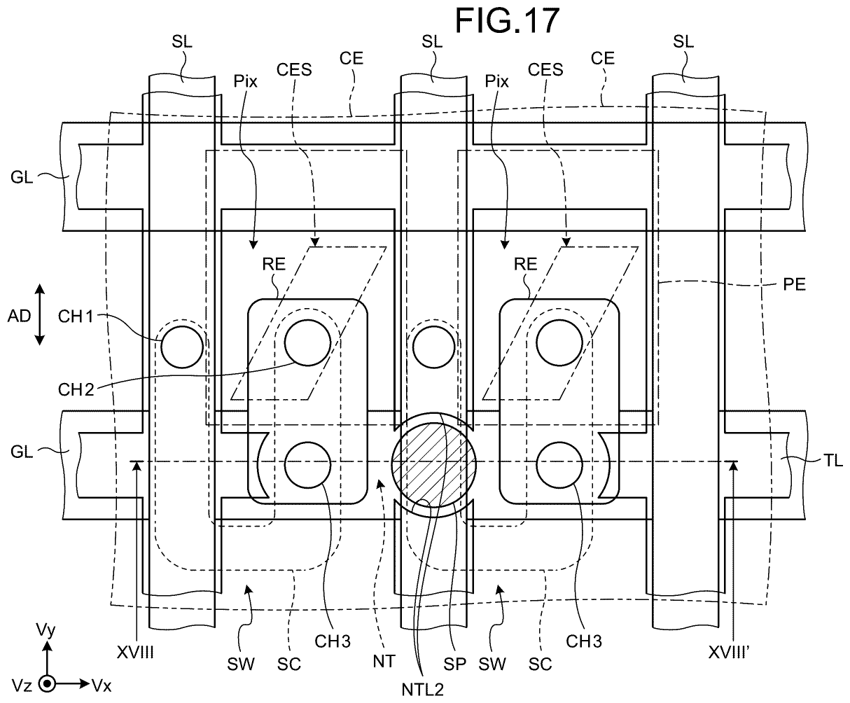

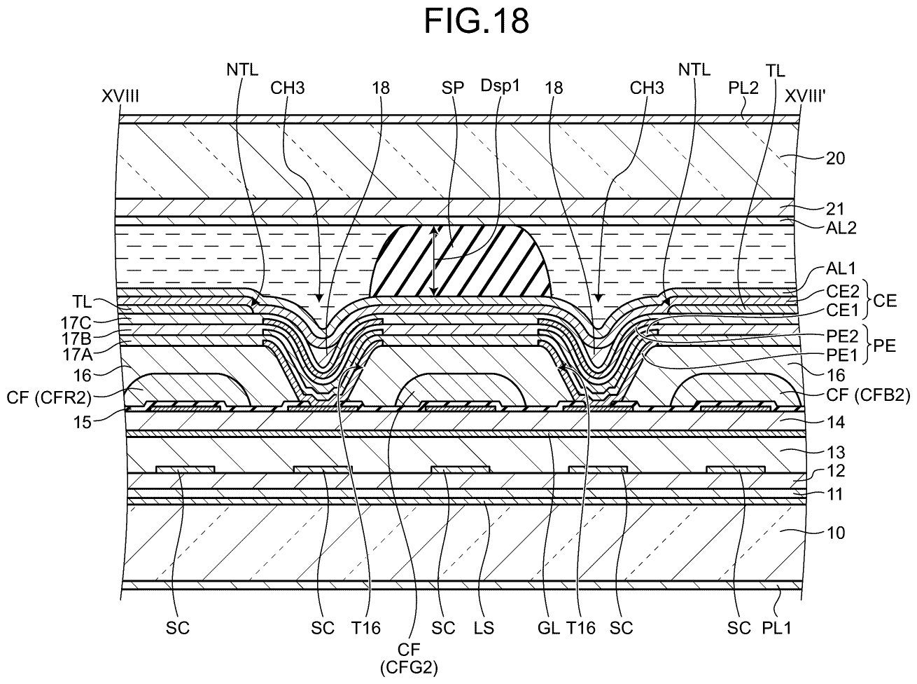

FIG. 17 is a schematic diagram schematically illustrating part of the display region in a fourth embodiment in an enlarged manner. FIG. 18 is a sectional view schematically illustrating an example of a section along XVIII-XVIII′ in FIG. 13 according to the fourth embodiment. In the following description, any constituent component same as in the first and second embodiments is denoted by the same reference sign, and duplicate description thereof is omitted.

In the fourth embodiment, no second flattening film 19 is provided unlike the first embodiment. As illustrated in FIG. 16, in a case in which the conductive layer TL is formed along a tilt surface T16 of the sixth insulating film 16, the conductive layer TL is tilted along a recessed part due to each contact hole CH3. With metal glazing of the conductive layer TL, reflected light LL in exposure is tilted with respect to a direction perpendicular to the front surface of the first insulation substrate 10. As a result, part of the material of the spacer SP during deposition flows into the recess of the first flattening film 18, and the thickness Dsp1 of the spacer SP decreases to the thickness Dsp2.

As illustrated in FIGS. 17 and 18, however, in the fourth embodiment, a region overlapping the contact hole CH3 is a region NL in which the conductive layer TL is not formed. With this configuration, reflected light LL in exposure is reduced, and accordingly, the solidification state of the spacer SP is stabilized. As a result, part of the material of the spacer SP during deposition is unlikely to flow into the recess of the first flattening film 18, and the thickness Dsp1 of the spacer SP is likely to be uniform.

Preferable embodiments are described above, but the present disclosure is not limited to such embodiments. Contents disclosed in the embodiments are merely exemplary, and various kinds of modifications are possible without departing from the scope of the present disclosure. Any modification performed as appropriate without departing from the scope of the present disclosure belongs to the technical scope of the present disclosure.

What is claimed is:

1. A display device comprising:
an array substrate; and
a counter substrate facing the array substrate,
wherein the array substrate includes
a plurality of signal lines arranged at an interval in a first direction,
a plurality of scanning lines arranged at an interval in a second direction,
a color filter disposed at a position overlapping each opening surrounded by two adjacent signal lines and two adjacent scanning lines,
a plurality of pixel electrodes disposed for respective pixels,
a plurality of semiconductors disposed for respective pixels,
a common electrode superimposed on the plurality of pixel electrodes with an insulating film interposed between the common electrode and the plurality of pixel electrodes,
an insulating film covering the color filters,
a contact hole that is a recessed part opened through the insulating film and electrically couples the pixel electrode and the semiconductor,
a first flattening film that is insulating and fills the recessed part of the contact hole,
a second flattening film overlapping at least the scanning lines and the first flattening film and directly covering the first flattening film from above, and
a spacer that is made of resin, is disposed at each of parts where the signal lines intersect the scanning lines in a plan view, and regulates the distance between the array substrate and the counter substrate.

2. The display device according to claim 1, wherein the second flattening film is shaped in strips along the scanning lines in a plan view.

3. The display device according to claim 2, wherein the area of each strip of the second flattening film is smaller than the area of a corresponding scanning line in a plan view.

4. The display device according to claim 1, further comprising a conductive layer having a lattice shape and overlapping the plurality of signal lines and the plurality of scanning lines in a plan view, wherein the second flattening film has a lattice shape overlapping the conductive layer.

5. The display device according to claim 1, further comprising a conductive layer overlapping at least part of the scanning lines in a plan view, wherein a region overlapping the spacer is a region in which the conductive layer is not formed.

6. A display device comprising:
an array substrate; and
a counter substrate facing the array substrate, wherein
the array substrate includes
a plurality of signal lines arranged at an interval in a first direction,
a plurality of scanning lines arranged at an interval in a second direction,
a color filter disposed at a position overlapping each opening surrounded by two adjacent signal lines and two adjacent scanning lines,
a plurality of pixel electrodes disposed for respective pixels,
a plurality of semiconductors disposed for respective pixels,
a common electrode superimposed on the plurality of pixel electrodes with an insulating film interposed between the common electrode and the plurality of pixel electrodes,
an insulating film covering the color filters,
a first contact hole that is a first recessed part opened through the insulating film and electrically couples a first pixel electrode among the plurality of pixel electrodes and the semiconductor,
a flattening film that is insulating and fills the recessed part of the first contact hole,
a second contact hole that is a second recessed part opened through the insulating film and electrically couples a second pixel electrode among the plurality of pixel electrodes and the semiconductor,
a flattening film that is insulating and fills the recessed part of the second contact hole, and
a first spacer that is made of resin, is disposed at each of parts where the signal lines intersect the scanning lines in a plan view, and regulates the distance between the array substrate and the counter substrate, and a second spacer that is made of resin, is disposed at each of other parts where the signal lines intersect the scanning lines, and regulates the distance between the array substrate and the counter substrate,
the thickness of the flattening film that is insulating and fills the recessed part of the first contact hole is larger than the thickness of the flattening film that is insulating and fills the recessed part of the second contact hole, and
the thickness of the first spacer is larger than the thickness of the second spacer.

7. A display device comprising:
an array substrate; and
a counter substrate facing the array substrate, wherein
the array substrate includes
a plurality of signal lines arranged at an interval in a first direction,
a plurality of scanning lines arranged at an interval in a second direction,
a color filter disposed at a position overlapping each opening surrounded by two adjacent signal lines and two adjacent scanning lines,
a plurality of pixel electrodes disposed for respective pixels,
a plurality of semiconductors disposed for respective pixels,
a common electrode superimposed on the plurality of pixel electrodes with an insulating film interposed between the common electrode and the plurality of pixel electrodes,
an insulating film covering the color filters,
a contact hole that is a recessed part opened through the insulating film and electrically couples the pixel electrode and the semiconductor,
a first flattening film that is insulating and fills the recessed part of the contact hole,
a spacer that is made of resin, is disposed at each of parts where the signal lines intersect the scanning lines in a plan view, and regulates the distance between the array substrate and the counter substrate, and
a conductive layer overlapping at least part of the scanning lines, and
a region overlapping the spacer is a region in which the conductive layer is not formed.

8. A display system comprising:
a lens;
the display device according to claim 1; and
a control device configured to output an image to the display device.
